(19) United States
(12) Patent Application Publication
(10) Pub. No.: US 2010/0012954 A1
(43) Pub. Date: Jan. 21, 2010

(54) Vertical III-Nitride Light Emitting Diodes on Patterned Substrates with Embedded Bottom Electrodes

(76) Inventors: Chen-Hua Yu, Hsin-Chu (TW); Chia-Lin Yu, Sigang (TW); Wen-Chih Chiou, Miaoli (TW); Ding-Yuan Chen, Taichung (TW); Hung-Ta Lin, Hsin-Chu (TW)

Correspondence Address: SLATER & MATSIL, L.L.P., 17950 PRESTON ROAD, SUITE 1000, DALLAS, TX, 75252, US

(21) Appl. No.: 12/191,033

(22) Filed: Aug. 13, 2008

Related U.S. Application Data
(60) Provisional application No. 61/082,381, filed on Jul. 21, 2008.

(51) Int. Cl. H01L 33/00; H01L 21/00

(52) U.S. Cl. 257/88; 438/34; 257/E33.001; 257/E21.001

(57) ABSTRACT

A light emitting diode (LED) device is presented. The LED device includes a substrate, a layered LED structure, and an embedded bottom electrode. The layered LED structure includes a buffer/nucleation layer disposed on the substrate, an active layer, and a top-side contact. A first-contact III-nitride layer is interposed between the buffer/nucleation layer and the active layer. A second-contact III-nitride layer is interposed between the active well layer and the top-side contact. A bottom electrode extends through the substrate, through the buffer/nucleation layer and terminates within the first-contact III-nitride layer.

This application claims priority to U.S. Provisional Patent Application Ser. No. 61/082,381, filed Jul. 21, 2008, and entitled “Vertical III-Nitride Light Emitting Diodes on Patterned Substrates with Embedded Bottom Electrodes,” which application is hereby incorporated herein by reference.

### TECHNICAL FIELD

The present invention relates generally to LEDs and more particularly vertical III-nitride light emitting diodes on patterned substrates with embedded bottom electrodes.

### BACKGROUND

Light emitting diodes (LEDs) are manufactured by forming active regions on a substrate and by depositing various conductive and semiconductive layers on the substrate. The radiative recombination of electron-hole pairs can be used for the generation of electromagnetic radiation by the electric current in a p-n junction. In a forward-biased p-n junction fabricated from a direct band gap material, such as GaAs or GaN, the recombination of the electron-hole pairs injected into the depletion region causes the emission of electromagnetic radiation. The electromagnetic radiation may be in the visible range or may be in a non-visible range. Different colors of LEDs may be created by using materials with different band gaps. Further, an LED with electromagnetic radiation emitting in a non-visible range may direct the non-visible light towards a phosphor lens or a like material type. When the non-visible light is absorbed by the phosphor, the phosphor emits a visible light.

LEDs may be manufactured on an insulating unpatterned substrate wafer. One process allows an n-metal contact to be placed on the top-side or light emitting side of the LED, limiting the light emitting surface of the LED. With both electrodes (n-metal and p-metal) on the same side, the active area and the emitting efficiency may be reduced. Moreover, dry etching to expose the n-type III-nitride layer may result in side-wall damage and further reduce efficiency.

Another conventional method interposes a p-metal layer between a p-type III-nitride layer and a conductive layer. This processes uses wafer bonding LED fabrication processes and removes the insulating substrate. The disadvantage of this method is that a non-uniform joint between the conductive substrate and the LED chip may degrade the LED performance. Further, removing insulating substrates may degrade yield. Moreover, these conventional processes are complex and therefore costly.

### SUMMARY OF THE INVENTION

These and other problems are generally solved or circumvented, and technical advantages are generally achieved by light emitting diodes (LEDs) and a method of manufacturing, and more particularly vertical III-nitride light emitting diodes on patterned substrates.

In accordance with an illustrative embodiment, a light emitting diode (LED) device is presented. The LED device comprises a substrate, a layered LED structure, and an embedded bottom electrode. The layered LED structure includes a buffer/nucleation layer disposed on the substrate, an active layer, and a top-side contact. A first-contact III-nitride layer is interposed between the buffer/nucleation layer and the active layer. A second-contact III-nitride layer is interposed between the active layer and the top-side contact. A bottom electrode extends through the substrate, through the buffer/nucleation layer and terminates within the first-contact III-nitride layer.

An advantage of an illustrative embodiment of the present invention includes providing a method to manufacture LEDs that may reduce complexity and cost. Moreover, an illustrative embodiment may lower defects and increase yield by the elimination of the top side etch, thus reducing process damage to the LED.

The foregoing has outlined rather broadly the features and technical advantages of an illustrative embodiment in order that the detailed description of the invention that follows may be better understood. Additional features and advantages of an illustrative embodiment will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the illustrative embodiments as set forth in the appended claims.

### BRIEF DESCRIPTION OF THE DRAWINGS

For a more complete understanding of the illustrative embodiments, and the advantages thereof, reference is now made to the following descriptions taken in conjunction with the accompanying drawings, in which:

FIG. 1 illustrates an embodiment of an LED comprising a patterned substrate;

FIG. 2 shows several examples of shapes that may be patterned into the LED substrate;

FIG. 3 shows a process flow of an illustrative embodiment; and

FIG. 4 shows an embodiment of an LED comprising a patterned substrate with air gaps.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that an illustrative embodiment provides many applicable inventive concepts that can be embodied in a wide variety of specific contexts. The specific embodiments discussed are merely illustrative of specific ways to use the inventive method, and do not limit the scope of the invention.

The present invention will be described with respect to illustrative embodiments in a specific context, namely a semiconductor LED. The invention may also be applied, however, to other semiconductor devices.

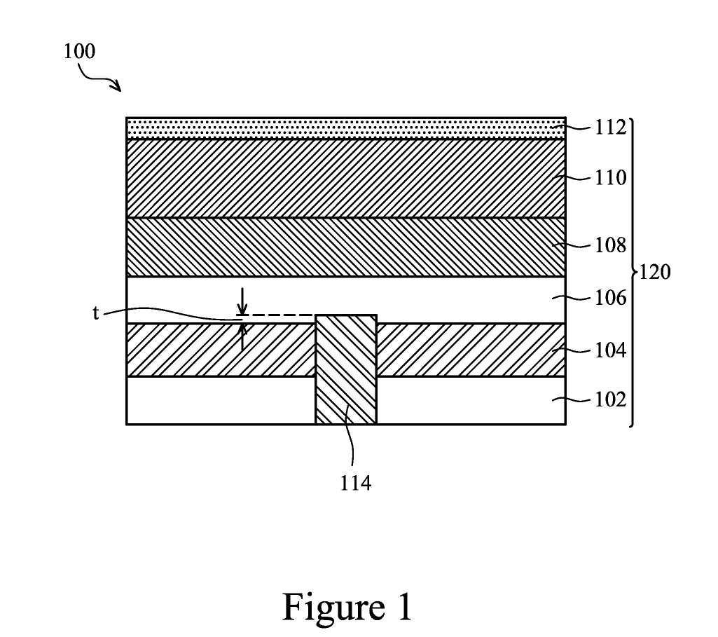

With reference now to FIG. 1, there is shown a first embodiment of an LED comprising a patterned substrate, with an embedded bottom electrode, in accordance with an illustrative embodiment. LED 100 includes substrate 102, with LED structure 120 formed thereon. Substrate 102 may comprise a conductive substrate or a non-conductive substrate. Examples of a non-conductive substrate 102 may be sapphire, MgAl₂O₄, oxide monocrystalline, or the like. Examples of a semi-conductive substrate 102 may be GaN, Si, Ge, SiC, SiGe, ZnO, ZnS, ZnSe, GaP, GaAs, or the like. Substrate 102 may be about 200 μm to about 600 μm in thickness, for example. Epitaxial films forming LED structure 120 are grown on substrate 102 and comprise buffer/nucleation layer 104, first-contact III-nitride layer 106, active layer 108, second-contact III-nitride layer 110, and top-side contact 112.

Buffer/nucleation layer 104 may comprise a low or high temperature grown III-nitride layer, a III-nitride-based superlattice layer, a metal carbon-nitride layer, a polysilicon layer, or the like and may be in the thickness range of about 20 nm to about 100 nm. A superlattice is a multiple stacked layer structure and comprises two types of nitride-based materials with different bandgaps. For example, a superlattice may have a total thickness between about 1 nm-1 μm wherein each nitride material layer has a thickness between about 0.1 nm to about 50 nm. A III-nitride may comprise GaN, InN, AlN, AlₓGa₍₁₋ₓ₎N, AlₓIn₍₁₋ₓ₎N, AlₓIn_{y}Ga_{(1-x-y)}N, combinations thereof, or the like. Buffer/nucleation layer 104 may be an insulating layer.

In an embodiment, buffer/nucleation layer 104 may be reflective. The material itself may be reflective, or a distributed Bragg reflector (DBR) may or may not be included in addition to, incorporated into, or instead of, buffer/nucleation layer 104. A DBR may be comprised of alternating layers of materials with differing diffraction indexes or the like. When buffer/nucleation layer 104 is reflective, LED 100 is a top emitting LED and the power output from the top-side may be greater than an illustrative embodiment in which buffer/nucleation layer 104 is non-reflective.

First-contact III-nitride layer 106 is disposed on buffer/nucleation layer 104. First-contact III-nitride layer 106 may be in the range of about 1 μm to about 4 μm thick. Example material for first-contact III-nitride layer 106 is GaN:Si or GaN:Mg disposed by a MOCVD, MBE, HVPE, LPE process, or the like.

Active layer 108 is disposed on first-contact III-nitride layer 106. Active layer 108 may comprise multiple quantum wells (MQW) or heterostructure. Active layer 108 may be layers of InGaN and GaN, for example. Active layer 108 may have 1 QW or there may be any number of QWs including 3 or 5. QW layers, for example, each may be about 30 Å to about 100 Å thick. Further active layer 108 may be a heterostructure, which may have a thicker well than in a MQW and may have only one pair of QWs. Active layer 108 may be disposed in an epitaxial reactor.

Second-contact III-nitride layer 110 is disposed on active layer 108. Second-contact III-nitride layer 110 may be grown in an epitaxial reactor to about 100-500 nm thick and comprise GaN:Mg, GaN:Si, or the like.

Top-side contact 112 is disposed on top of second-contact III-nitride layer 110. Example methods to contact the emission face of the LED, may include the use of a transparent conductive material, such as indium tin oxide (ITO). Further, a metal pad may be attached to the ITO coating. Top-side contact 112 may be comprised of Ni, Au, ITO, combinations thereof, or the like, at a thickness of about 10 nm to about 50 nm, for example. Top-side contact 112 may be disposed on to LED 100 in a sputtering, E-beam process, or the like.

Bottom electrode 114 extends through substrate 102 and buffer/nucleation layer 104 and into first-contact III-nitride layer 106. Bottom electrode 114 may extend into first-contact III-nitride layer 106 a distance “t.” “t” may be about 0.02 μm to about 0.8 μm thick, for example, but more preferably about 0.5 μm.

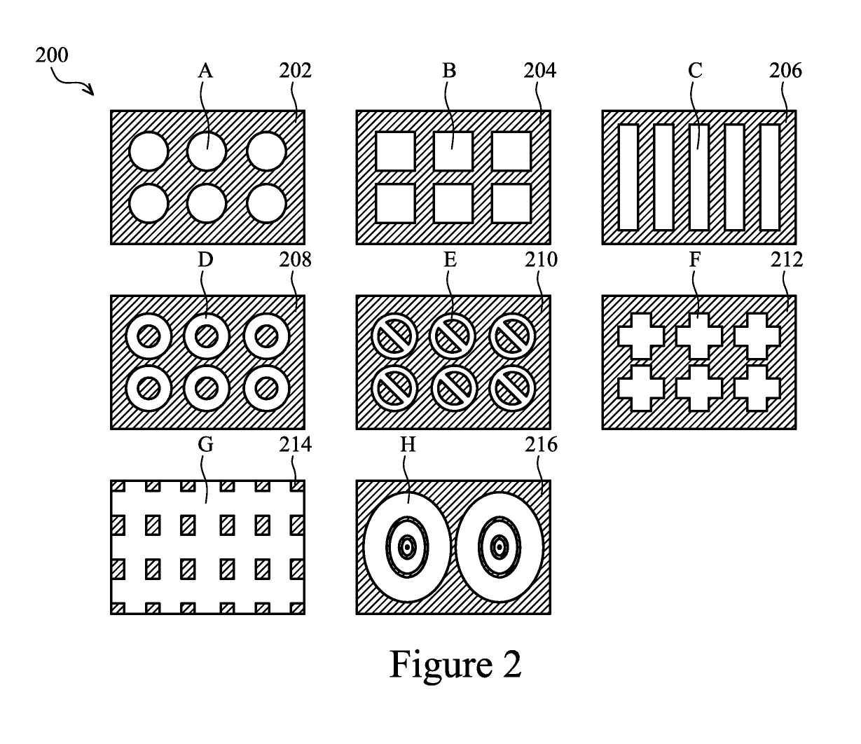

FIG. 2 shows bottom views of several LED structures with bottom electrode shapes incorporated within. In each example LED 202-216, the light area is the bottom electrode region, such as bottom electrode 114 in FIG. 1 and the dark area is the substrate, such as substrate 102 in FIG. 1. From the bottom of an illustrative embodiment, the bottom electrodes may appear as shapes such as shapes A-H in FIG. 2. LED 202 includes a circular bottom electrode A. LED 204 and 206 include a square bottom electrode B and a rectangle bottom electrode C, respectively. LED 208 includes bottom electrode D with ring shaped bottom electrodes. LED 210 includes a bar-ring shaped contact E. LED 212 includes a polygon shaped bottom electrode F. LED 214 includes a grid shaped bottom electrode G and LED 216 includes a concentric ring shaped bottom electrode H. Examples A-H are only illustrative of a few of the bottom electrode shapes that may be incorporated into an LED embodiment. Further, while FIG. 2 illustrates the same shape bottom electrodes within an LED, the scope of the illustrative embodiments are not so limited, and a mixture of shapes and sizes for the bottom electrodes may comprise a single LED.

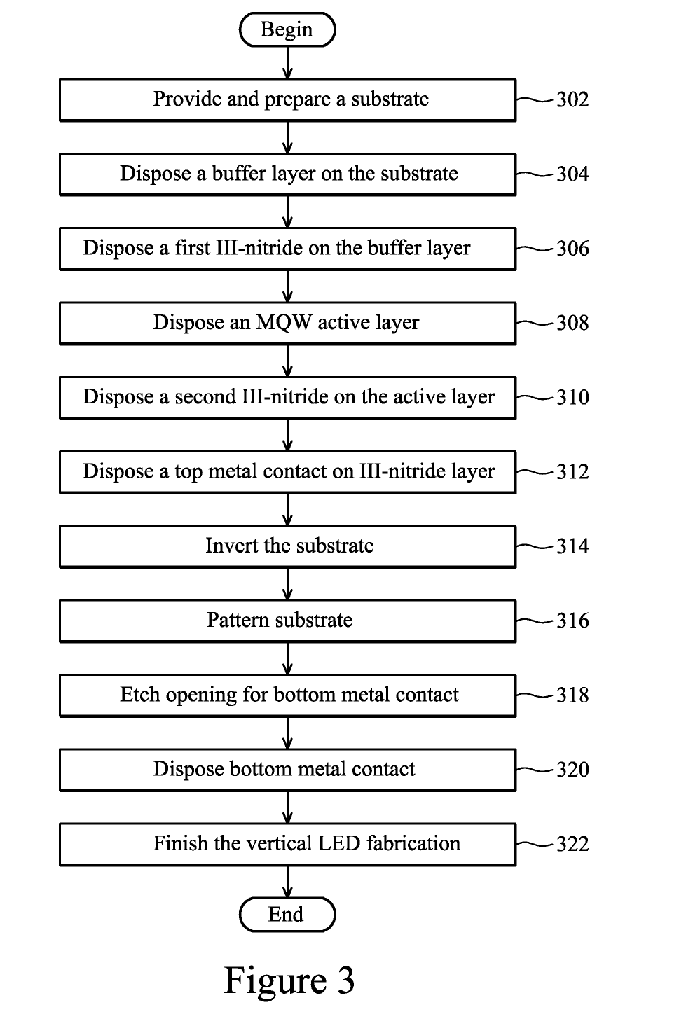

FIG. 3 shows a process flow of an illustrative embodiment. The process begins with providing and preparing a substrate (step 302). The substrate may be sapphire, MgAl₂O₄, oxide monocrystalline, GaN, Si, Ge, SiC, SiGe, ZnO, ZnS, ZnSe, GaP, GaAs, or the like. The substrate may be prepared by annealing at a high temperature. This may be a gettering process step to remove contamination from the substrate.

A buffer/nucleation layer is disposed or grown on the substrate (step 304) using an epitaxial process. Epitaxial films are an ordered crystalline growth layer typically formed on a monocrystalline substrate or layer. Epitaxial films may be grown from gaseous or liquid precursors. Because the substrate (or precursor layer) acts as a seed crystal, the epitaxially grown film takes on a lattice structure and orientation of the substrate. In contrast, other thin-film deposition methods may deposit polycrystalline or amorphous films, even on single-crystal substrates. Heteroepitaxy is the process of depositing an epitaxial layer on a substrate of a different composition. A precursor may be provided to allow for epitaxial growth on a multicrystalline layer.

For example, the buffer/nucleation layer may be comprised of a low temperature grown AlN layer. AlN has a hexagonal crystal structure and a large band gap and may be disposed by a molecular-beam epitaxy (MBE), metal organic chemical vapor deposition (MOCVD), hydride vapor phase epitaxy (HVPE), or liquid phase epitaxy (LPE) process.

In MBE, a source material is heated to produce an evaporated beam of particles. The beam of particles is deposited in a high vacuum (10⁻⁸ Pa), where the beam of particles condenses into a layer. In a MOCVD process, the formation of the epitaxial layer occurs by final pyrolisis of the constituent chemicals at the substrate surface. In contrast to MBE, the growth of crystals in a MOCVD process is by chemical reaction and not physical deposition. HVPE is an epitaxial growth technique, which may use carrier gasses such as ammonia, hydrogen and various chlorides. LPE is a method to grow crystal layers from the melt on solid substrates. The buffer/nucleation layer may comprise multiple epitaxial layers.

The first-contact III-nitride layer is disposed on the buffer/nucleation layer (step 306). In an N-DOWN LED structure, the first-contact III-nitride layer may comprise an n-type III-nitride GaN with Si doping, for example. In an N-UP LED structure, the first-contact III-nitride layer may comprise a p-type III-nitride, GaN with Mg doping, for example.

An MQW active layer is disposed on the first-contact III-nitride layer (step 308). The MQW active layer may be comprised of multiple layers forming multiple quantum wells.

A second-contact III-nitride layer is disposed on the active layer (step 310). In an N-DOWN LED structure, the second-contact III-nitride layer may comprise a p-type III-nitride GaN with Mg doping, for example. In an N-UP LED structure, the second-contact III-nitride layer may comprise an n-type III-nitride, GaN with Si doping, for example.

The top metal contact is disposed on the second-contact III-nitride layer (step 312).

Following the top metal disposition, the substrate is inverted (step 314). The backside of the substrate is patterned (step 316). The backside of the substrate may be patterned, for example, by depositing a photoresist over the surface of the backside of the substrate. Using a mask, which has transparent regions or opaque regions in the pattern of the bottom electrodes (see FIG. 2), patterning the photoresist, by light exposure, for example.

The substrate may then be etched (step 318) using a dry etch process with Ar, for example. The etch process or processes will etch through the substrate, the buffer/nucleation layer, and into the first-contact III-nitride layer. A distance “t” into the first-contact III-nitride layer may be in the range of about 0.02 μm to about 0.8 μm. The etch process will preferably be accomplished in a single etch chamber.

The bottom electrode is then disposed on the substrate (step 320). In an N-DOWN LED structure, the bottom electrode will comprise an n-metal. In an N-UP LED structure, the bottom electrode will comprise a p-metal. The process may continue so as to finish vertical LED fabrication (step 322). Standard processing may comprise ICP-RIE etch, wet etch, photo enhanced chemical etching and the like.

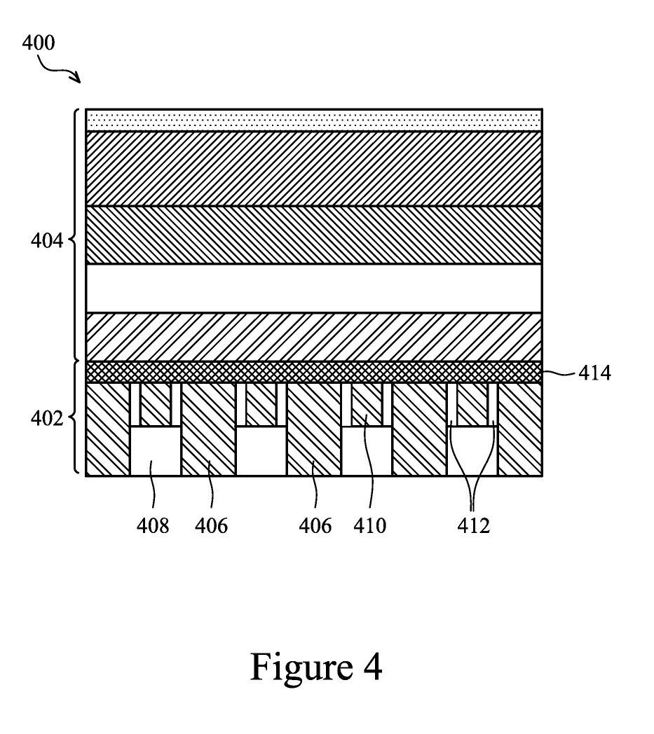

Turning now to FIG. 4, another illustrative embodiment of a patterned substrate with a bottom electrode LED is presented. A silicon on insulator (SOI), patterned bottom electrode, LED 400, has an SOI substrate 402. Silicon on insulator or SOI refers to the use of a layered silicon-insulator-silicon substrate. In an embodiment, the insulator may comprise silicon dioxide. However, the insulator may comprise sapphire, or the like.

SOI, patterned bottom electrode, LED 400 may be comprised of an LED structure, such as LED structure 104, as discussed in FIG. 1. Comprising, for example, a buffer/nucleation layer, a first-contact III-nitride layer, an active layer, a second-contact III-nitride layer, and a top metal contact layer. Bottom electrode 406 is comprised of electro-plated Ni or the like. Bottom Si layer 408 is the portion of the bottom layer of the SOI substrate, which remains un-etched. Silicon dioxide layer 410 is the insulator portion of SOI substrate 402. Air gaps 412 may be formed during the patterned bottom electrode etch, as further described below.

After a top metal contact layer is disposed on the second-contact III-nitride layer, the substrate is inverted, patterned, and etched. As the etch proceeds through bottom Si layer 408 of SOI substrate 402 and into insulator layer 410 of SOI substrate 402, the etch rate changes due to the material change, and the etched opening may be larger in the case of a silicon dioxide insulator layer 110 than in bottom silicon layer 108. The etch process stops in the top silicon layer 114 of SOI substrate 102. The top silicon layer may be doped to conduct charge. The dopant selected may be n-type in an N-DOWN LED structure, and may be p-type in an N-UP LED structure. Nickel may then be electroplated into the etched openings. The electroplating process, disposing a substantially vertical column of nickel, may cause air gaps 412 to be formed between bottom electrode 406 and silicon dioxide layer 410.

Although the illustrative embodiment and its advantages have been described in detail, it should be understood that various changes, substitutions, and alterations can be made herein without departing from the spirit and scope of the invention as defined by the appended claims. For example, it will be readily understood by those skilled in the art that other forms of semiconductor devices may benefit from the illustrative embodiments, including LEDs with additional circuitry and components not including LEDs, while remaining within the scope of the present invention.

Moreover, the scope of the present application is not intended to be limited to the particular embodiments of the process, machine, manufacture, composition of matter, means, methods, and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A light emitting diode (LED) device comprising:
a substrate;
a layered LED structure comprising:
a buffer/nucleation layer disposed on the substrate;
an active layer; and
a top-side contact, wherein a first-contact III-nitride layer is interposed between the buffer/nucleation layer and the active layer, and wherein a second-contact III-nitride layer is interposed between the active layer and the top-side contact; and
a bottom electrode, wherein the bottom electrode extends through the substrate, through the buffer/nucleation layer and terminates within the first-contact III-nitride layer.

2. The LED device of claim 1, wherein the substrate is selected from a group consisting of sapphire, MgAl2O4, oxide monocrystalline, GaN, Si, Ge, SiC, SiGe, ZnO, ZnS, ZnSe, GaP, and GaAs.

3. The LED device of claim 1, wherein the substrate comprises a silicon on insulator (SOI) substrate.

4. The LED device of claim 1, wherein the substrate is non-conductive or semi-conductive.

5. The LED device of claim 1, wherein the buffer/nucleation layer comprises a III-nitride layer, a III-nitride-based superlattice layer, a metal carbon-nitride layer, or a polysilicon layer.

6. The LED device of claim 5, wherein the III-nitride comprises GaN, InN, AlN, AlₓGa₍₁₋ₓ₎N, AlₓIn₍₁₋ₓ₎N, AlₓIn_{y}Ga_{(1-x-y)}N or combinations thereof.

7. The LED device of claim 1, wherein the substrate thickness is between about 200 μm and about 600 μm.

8. The LED device of claim 1, wherein the active layer is comprised of multiple quantum wells or heterostructures.

9. The LED device of claim 1, wherein the bottom electrode is comprised of nickel.

10. The LED device of claim 1, wherein the bottom electrode terminates a distance “t” within first-contact III-nitride layer, and wherein “t” is between about 0.02 μm and about 0.8 μm.

11. The LED device of claim 1, wherein the bottom electrode comprises n-metal.

12. The LED device of claim 1, wherein the bottom electrode comprises circles, squares, rectangles, ovals, lines, spirals, other shapes, and combinations thereof.

13. A method of manufacturing a plurality of light emitting diodes (LEDs), the method comprising:
providing a substrate;
disposing epitaxial layers on the substrate forming a plurality of LED structures, the LED structure method comprising:
disposing a buffer/nucleation layer on the substrate;
disposing an active layer; and
disposing a top-side contact, wherein a first-contact III-nitride layer is interposed between the buffer/nucleation layer and the active layer, and wherein a second-contact III-nitride layer is interposed between the active layer and the top-side contact;
removing portions of the substrate, the buffer/nucleation layer, and the first-contact III-nitride layer, thereby forming open regions; and
disposing a conductor in the open regions, forming a bottom electrode, wherein the bottom electrode extends through the substrate, through the buffer/nucleation layer and terminates within the first-contact III-nitride layer.

14. The method of claim 13, wherein the removing portions of the substrate, the buffer/nucleation layer and the first-contact III-nitride layer is accomplished by etch methods comprising ICP, RIE, chemical etching, photo enhance chemical etching, or combinations thereof.

15. The method of claim 13, wherein the removing portions of the substrate is accomplished by polishing the substrate to a thickness of between about 50 μm to about 100 μm.

16. The method of claim 13, wherein the open regions comprise circles, squares, rectangles, ovals, lines, spirals, other shapes, and combinations thereof.

17. The method of claim 13, wherein the substrate is selected from the group consisting of sapphire, MgAl2O4, oxide monocrystalline, GaN, Si, Ge, SiC, SiGe, ZnO, ZnS, ZnSe, GaP, and GaAs.

18. The method of claim 13, wherein the first-contact III-nitride layer and the second-contact III-nitride layer are grown in a MOCVD, MBE, HVPE, or LPE process.

19. A light emitting diode (LED) device comprising:
a substrate;
a layered LED structure; and
a bottom electrode, wherein the bottom electrode extends through the substrate, contacting a first-contact III-nitride layer, and wherein the bottom electrode is comprised of nickel.

20. The LED device of claim 19, wherein the bottom electrode terminates a distance “t” within the first-contact III-nitride layer, and wherein “t” is between about 0.02 μm and about 0.8 μm.
